(19) United States
(12) Patent Application Publication
(10) Pub. No.: US 2026/0324469 A1
(43) Pub. Date: Oct. 15, 2026

(54) INTERPOSER STRUCTURE AND MANUFACTURING METHOD THEREOF

(71) Applicant: KORE SEMICONDUCTOR CO., LTD., Qingdao (CN)

(72) Inventors: Ching-Yu NI, Qingdao (CN); Wei-Ming CHEN, Qingdao (CN)

(21) Appl. No.: 19/644,129

(22) Filed: Apr. 10, 2026

(30) Foreign Application Priority Data
Apr. 11, 2025 (CN) 202510458153.9

(51) Int. Cl. H10W 70/65

(52) U.S. Cl. CPC H10W 70/65

(57) ABSTRACT

Provided are an interposer structure and a manufacturing method thereof, in which a first circuit portion and a second circuit portion are respectively formed on opposite sides of an interposer body to balance the stress of the interposer structure, thereby avoiding warpage concerns in subsequent applications.

### BACKGROUND

### TECHNICAL FIELD

The present disclosure relates to a semiconductor structure and a manufacturing method thereof, and more particularly, to an interposer structure and a manufacturing method thereof.

### DESCRIPTION OF RELATED ART

With the vigorous development of the electronics industry, electronic products are gradually trending towards multi-function and high performance. Currently, technologies used in the field of chip package comprise, for example, chip scale package (CSP), direct chip attached (DCA) or multi-chip module (MCM) and other in kinds of flip chip package module or to integrate the chip package technology in stacking as the 3-dimensions integrated circuit (3D IC).

The conventional 3D IC package technology is to dispose a chip on the upper side of the through silicon interposer (TSI) having through–silicon vias (TSVs), and then dispose the through silicon interposer on a package substrate via the lower side of the through silicon interposer.

However, in the prior art, the formation of the TSI in the TSV would complicate the manufacturing process and increase material cost and the manufacturing time . As a result, the manufacturing cost of the package products cannot be decreased.

How to overcome the aforementioned shortcomings of the prior art thus has become an urgent issue to be resolved.

### SUMMARY

In view of the aforementioned shortcomings of the prior art, the present disclosure provides an interposer structure, which comprises: an interposer body having a first side, a second side opposite to the first side, a dielectric layer, and a wiring layer coupled to the dielectric layer; a first circuit portion disposed on the first side of the interposer body, wherein the first circuit portion comprises a first insulation layer and a first circuit layer coupled to the first insulation layer and electrically connected to the wiring layer; and a second circuit portion disposed on the second side of the interposer body, and comprising a second insulation layer and a second circuit layer coupled to the second insulation layer and electrically connected to the wiring layer.

The present disclosure also provides a manufacturing method of an interposer structure, comprising: forming an interposer body on a carrier of panel specification, wherein the interposer body is disposed on the carrier via the second side thereof and comprises a first side, a second side opposite to the first side, a dielectric layer and a wiring layer coupled to the dielectric layer; forming a first circuit portion on the first side of the interposer body and electrically connecting the first circuit portion to the interposer body, wherein the first circuit portion comprises a first insulation layer and a first circuit layer coupled to the first insulation layer and electrically connected to the wiring layer; removing the carrier; and forming a second circuit portion on the second side of the interposer body, wherein the second circuit portion comprises a second insulation layer and a second circuit layer coupled to the second insulation layer and electrically connected to the wiring layer.

In the aforementioned interposer package and the manufacturing method thereof, a line width/line spacing of the wiring layer is 0.6/0.6 micron.

In the aforementioned interposer package and the manufacturing method thereof, a line width/line spacing of the first circuit layer is greater than the line width/line spacing of the wiring layer.

In the aforementioned interposer package and the manufacturing method thereof, a line width/line spacing of the second circuit layer is greater than the line width/line spacing of the wiring layer.

In the aforementioned interposer package and the manufacturing method thereof, the interposer body is a back end of line (BEOL) wafer.

As can be understood from the above, in the interposer structure and the manufacturing method thereof, an interposer body with fine line width/fine line spacing specifications is produced, which reduces not only the number of the first circuit layers and/or the second circuit layers, but also decreases the thickness of the product using the same, so as to facilitate the thinning requirement of the product used in subsequent applications.

Moreover, by disposing the first circuit portion and the second circuit portion on opposite first and second sides of the interposer body, the structural stress of the interposer structure is balanced, and the products using the same are thus prevented from warpage concerns.

Furthermore, since TSV is not necessary to be applied in the interposer structure, the material cost and manufacturing time can be reduced, significantly cutting the manufacturing cost of a semiconductor package.

### BRIEF DESCRIPTION OF THE DRAWINGS

FIG. 1A to FIG. 1G are schematic cross-sectional views of the manufacturing method of the interposer structure according to the present disclosure.

FIG. 2 is schematic cross-sectional views of the subsequent applications of the interposer structure according to the present disclosure.

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

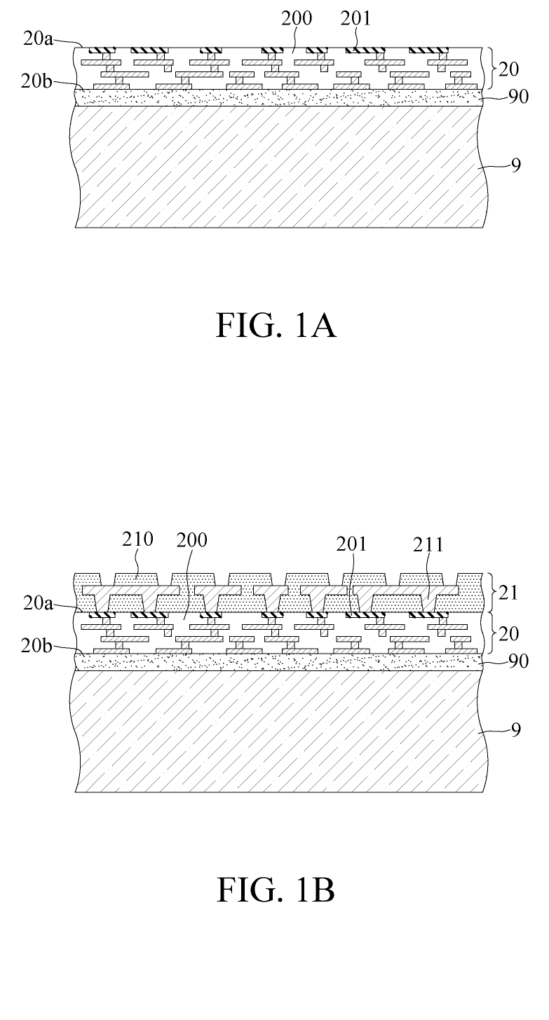

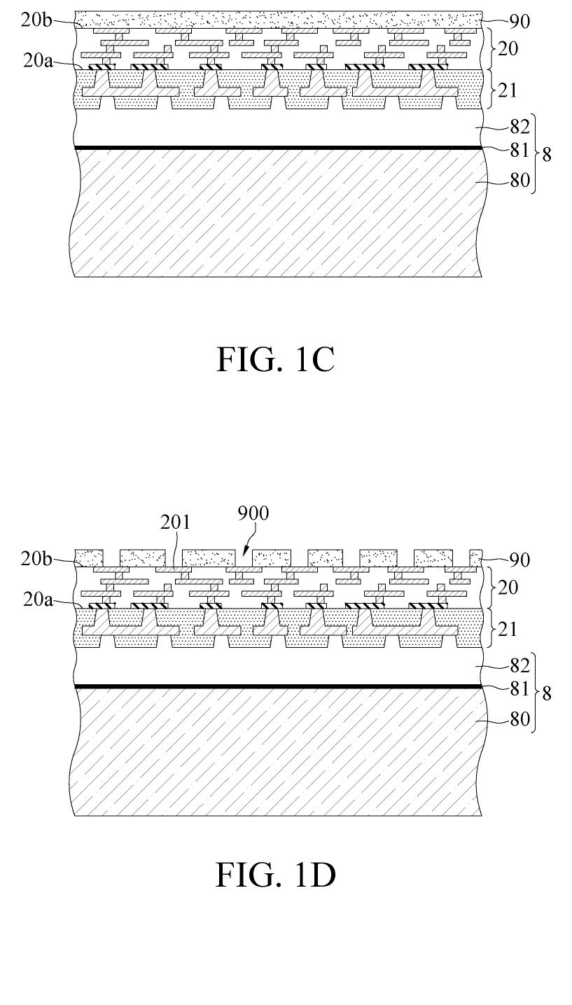

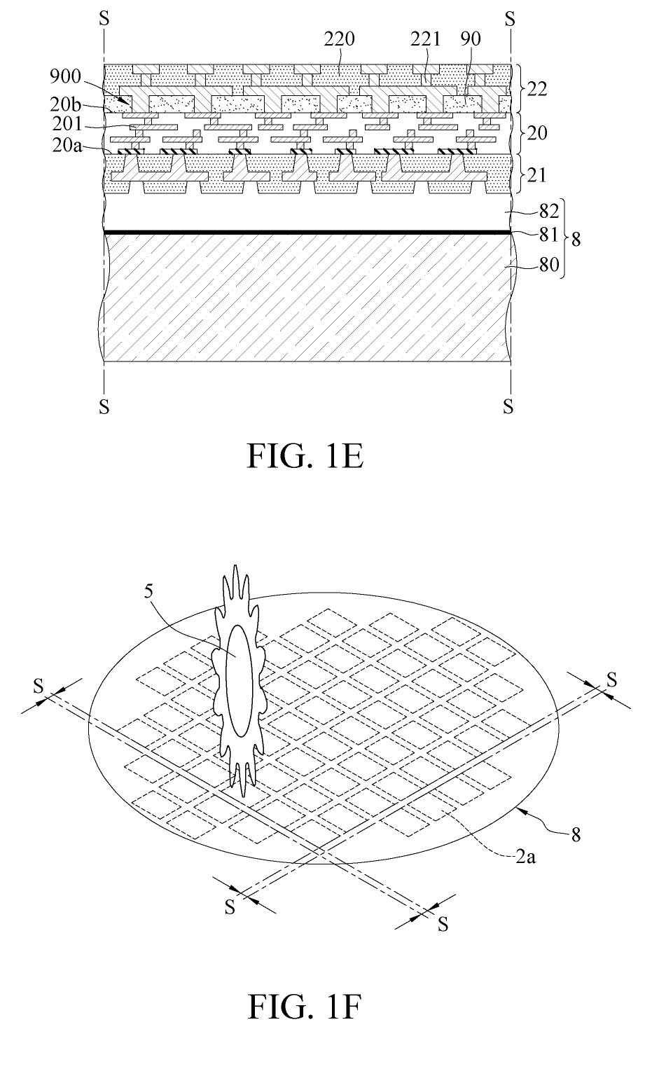

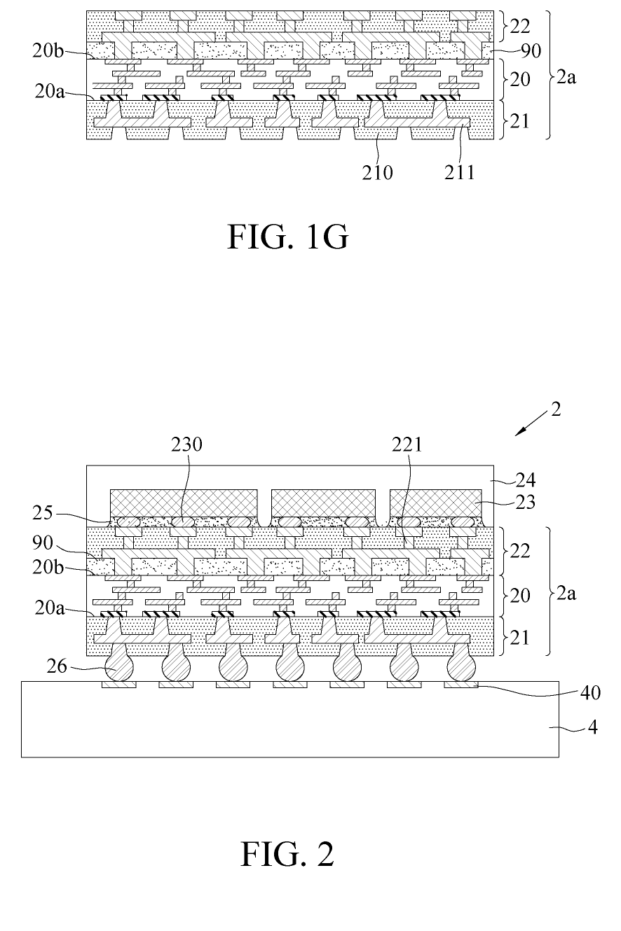

FIG. 1A to FIG. 1G are schematic cross-sectional views of the manufacturing method of the semiconductor package 2a according to the present disclosure. In one embodiment, the related manufacturing process of wafer level package specification is adopted.

As shown in FIG. 1A, a carrier 9 of panel specification is provided, which is disposed with a passivation layer 90 thereon, and an interposer body 20 is disposed on the passivation layer 90. The interposer body 20 has a first side 20a and a second side 20b opposite to the first side 20a, and the interposer 20 is disposed on the passivation layer 90 via the second side 20b thereof.

In one embodiment, the carrier 9 is a semiconductor board (for example, a silicon board) with a panel specification. The material of the passivation layer 90 is, for example, silicon dioxide or silicon nitride. The interposer body 20 is a back end of line (BEOL) wafer with the first side 20a being the front side and the second side 20b being the back side.

Furthermore, the interposer body 20 has at least a dielectric layer 200 and at least a wiring layer 201 coupled to (encapsulated by) the dielectric layer 200. For example, the dielectric layer 200 comprises Ajinomoto build-up film (ABF), Polybenzoxazole (PBO), Prepreg (PP) or other dielectric materials. The patterned electroplated copper or other approaches can be adopted to form a redistribution layer (RDL) on the wiring layer 201.

Additionally, the dielectric layer 200 is to be used as an inter-metal dielectric (IMD), and the line width/line spacing (L/S) of the wiring layer 201 is 0.6/0.6 micron (µm).

As shown in FIG. 1B, the first circuit portion 21 is formed on the first side 20a of the interposer body 20, and the interposer body 20 is electrically connected to the first circuit portion 21.

In one embodiment, the first circuit portion 21 has at least a first insulation layer 210 and at least a first circuit layer 211 coupled to (encapsulated by) the first insulation layer 210, and the wiring layer 201 is electrically connected to the first circuit layer 211. For example, the first insulation layer 210 is polyimide (PI) or other dielectric material, and the first circuit layer 211 can be formed as the RDL by using patterned electroplated metal material (such as copper, nickel, gold, tin, silver or other metals).

Moreover, a line width/line spacing of the first circuit layer 211 is greater than the line width/line spacing of the wiring layer 201.

As shown in FIG. 1C, a support structure 8 of panel specification is disposed on the first circuit portion 21, and the carrier 9 is then removed while the passivation layer 90 remains.

In one embodiment, the support structure 8 is a board body 80 of semiconductor material (such as, silicon or glass), and a release layer 81 and an adhesive layer 82 of a bonding material are formed sequentially on the support structure 8 by, for example, coating, so that the adhesive layer 82 is temporarily bonded on the first circuit portion 21.

Moreover, the removing process of the carrier 9 is carried out by grinding the silicon material to remove a majority thereof and then dry etching to remove the rest of the silicon material.

As shown in FIG. 1D, a plurality of openings 900 are formed through the passivation layer 90 to expose the wiring layer 201 from the plurality of openings 900.

In one embodiment, the patterned photoresist can be used to etch the passivation layer 90 to form the openings 900, and then the patterned photoresist is removed.

As shown in FIG. 1E, a second circuit portion 22 is formed on the passivation layer 90, and the interposer body 20 is electrically connected to the second circuit portion 22.

In one embodiment, the second circuit portion has at least a second insulation layer 220 and at least a second circuit layer 221 coupled to (encapsulated by) the second insulation layer 220. A part of the second circuit layer 221 extends to the openings 900 to be in contact with the wiring layer 201, so as for the wiring layer 201 to be electrically connected to the second circuit layer 221. For example, the second insulation layer 220 is made of polyimide (PI) or other dielectric material, and the RDL on the second circuit layer 221 can be formed by patterning the electroplated copper or other applicable processes.

Moreover, a line width/line spacing of the second circuit layer 221 is greater than the line width/line spacing of the wiring layer 201.

As shown in FIG. 1F and FIG. 1G, a singulation process is performed along a cutting path S shown in FIG. 1E to obtain a plurality of interposer structures 2a. The interposer structures 2a can be formed into a sandwich structure, of which the first side 20a and the second side 20b of the interposer body 20 are attached, respectively, to the first circuit portion 21 and the second circuit portion 22. Then, the support structure 8 is removed to expose the first insulation layer 210 and the first circuit layer 211 of the first circuit portion 21.

In one embodiment, the interposer structure 2a which has not yet been cut and separated, can be singulated by a separator 5 such as a knife, before a subsequent non-defective product picking process proceeds.

Furthermore, the board body 80, the release layer 81, and the adhesive layer 82 of the support structure 8 may be removed by physically peeling off the board body 80 and the release layer 81, etching off a majority of the adhesive layer 82, and laser debonding the rest part of the adhesive layer 82 to expose the first circuit portion 21.

In the subsequent manufacturing process, as shown in FIG. 2, at least a semiconductor element 23 is disposed on the second circuit portion 22 of the interposer structure 2a and encapsulated by the semiconductor element 23 by a packaging layer 24, and a plurality of conductive elements 26 such as conductive solder balls or conductive bumps are formed on the first circuit portion 21, such that the conductive elements 26 are electrically connected to the first circuit portion 21. And, the semiconductor package 2 is thus obtained.

The semiconductor elements 23 aforementioned are active components, inactive components or a combination thereof, wherein the active components are, for example, semiconductor chips and the inactive components are, for example, resistance, capacitors and inductance.

In one embodiment, the semiconductor element 23 is a semiconductor chip having an active circuit layer and electrically connected to the second circuit layer 221 by a plurality of conductive bumps 230 such as copper and/or solder material in a flip chip manner. For example, underfill 25 can be formed between the semiconductor element 23 and the second circuit portion 22 to encapsulate the plurality of conductive bumps 230 and then the underfill 25 and the semiconductor element 23 are encapsulated by the packaging layer 24. The underfill 25 is filled in order to fill the space between the lower surface of the semiconductor element 23 and the upper surface of the interposer structure 2a. Alternatively, formation of the underfill 25 can be omitted and the plurality of conductive bumps 230 and the semiconductor elements 23 are directly encapsulated by the packaging layer 24.

The packaging layer 24 is made of an insulation material such as polyimide (PI), dry film, and encapsulant or molding compound of epoxy resin.

In one embodiment, the packaging layer 24 is formed by a molding process to protect the semiconductor element 23 and cover the upper surface of the interposer structure 2a.

In addition, the semiconductor package 2 can be disposed on a plurality of electric contacts 40 of a package substrate 4 via the plurality of conductive elements 26, wherein the package substrate 4 is, for example, an ABF substrate, a Bismaleimide Triazine (BT) substrate, a PCB substrate, a ceramic substrate or other carrier boards.

Thus, the manufacturing method of the interposer structure of the present disclosure not only reduces the number of the first circuit layer 211 and/or the second circuit layer 221, but also decreases the thickness of the products (such as semiconductor package 2) having the interposer structure by using a back end of line (BEOL) wafer to manufacture the interposer body 20 with the fine line width/line spacing (L/S=0.6/0.6 um), which facilitates thinning the semiconductor package 2.

Furthermore, in the manufacturing method of the present disclosure, the RDL structure is formed on both upper and lower sides of the interposer body 20 (the first circuit portion 21 and the second circuit portion 22) to equalize the structural stress of the interposer structure 2a and prevent the products (such as the semiconductor package 2) having the same from warpage concerns.

Also, the manufacturing method of the present disclosure can significantly reduce the manufacturing cost of the products of subsequent applications (such as the semiconductor package 2) by omitting the manufacture of through silicon vias (TSV) in the interposer structure 2a, which can decrease material cost and manufacturing time.

The present disclosure also provides an interposer structure 2a, comprising: an interposer body 20, a first circuit portion 21, and a second circuit portion 22.

The interposer body 20 comprises a first side 20a, a second side 20b opposite to the first side 20a, at least a dielectric layer 200, and at least a wiring layer 201 encapsulated by the dielectric layer 200.

The first circuit portion 21 is disposed on the first side 20a of the interposer body 20, and comprises at least a first insulation layer 210 and at least a first circuit layer 211 coupled to the first insulation layer 210 and electrically connected to the wiring layer 201.

The second circuit portion 22 is disposed on the second side 20b of the interposer body 20, and comprises at least a second insulation layer 220 and at least a second circuit layer 221 coupled to the first insulation layer 210 and electrically connected to the wiring layer 201.

In one of embodiments, the line width/line spacing of the wiring layer 201 is 0.6/0.6 micron.

In one of embodiments, the line width/line spacing of the first circuit layer 211 is greater than the line width/line spacing of the wiring layer 201.

In one of embodiments, the line width/line spacing of the second circuit layer 221 is greater than the line width/spacing of the wiring layer 201.

In one of embodiments, the interposer body 20 is a back end of line (BEOL) wafer.

To sum up, in the interposer structure and the manufacturing method thereof, an interposer body with a fine line width/fine line spacing is produced, which not only reduces the number of the first circuit layers and/or the second circuit layers, but also decreases the thickness of the product using the same, facilitating the thinning of the product using the same.

Furthermore, by disposing the first circuit portion and the second circuit portion respectively on both upper and lower sides of the interposer body, the structural stress of the interposer structure is balanced, and the semiconductor package is thus prevented from the issue of warpage.

Besides, since TSV is not necessary to be applied in the interposer structure, material cost and manufacturing time can be reduced, whereby manufacturing cost of a semiconductor package can be significantly decreased.

The above embodiments are provided for illustrating the principles of the present disclosure and its technical effects, and should not be construed as limiting the present disclosure in any way. The above embodiments can be modified by one of ordinary skill in the art without departing from the spirit and scope of the present disclosure. Therefore, the scope of protection sought for the present invention should be defined by the following claims.

What is claimed is:

1. An interposer structure, comprising:
an interposer body having a first side, a second side opposite to the first side, a dielectric layer, and a wiring layer coupled to the dielectric layer;
a first circuit portion disposed on the first side of the interposer body and comprising a first insulation layer and a first circuit layer coupled to the first insulation layer and electrically connected to the wiring layer; and
a second circuit portion disposed on the second side of the interposer body and comprising a second insulation layer and a second circuit layer coupled to the second insulation layer and electrically connected to the wiring layer.

2. The interposer structure of claim 1, wherein a line width/line spacing of the wiring layer is 0.6/0.6 micron.

3. The interposer structure of claim 1, wherein a line width/line spacing of the first circuit layer is greater than a line width/line spacing of the wiring layer.

4. The interposer structure of claim 1, wherein a line width/line spacing of the second circuit layer is greater than a line width/line spacing of the wiring layer.

5. The interposer structure of claim 1, wherein the interposer body is a back end of line (BEOL) wafer.

6. A method of manufacturing an interposer structure, comprising:
forming an interposer body on a carrier of panel specification, wherein the interposer body comprises a first side, a second side opposite to the first side, a dielectric layer, and a wiring layer coupled to the dielectric layer, wherein the interposer body is disposed on the carrier via the second side thereof;
forming a first circuit portion on the first side of the interposer body and electrically connecting the first circuit portion to the interposer body, wherein the first circuit portion comprises a first insulation layer and a first circuit layer coupled to the first insulation layer and electrically connected to the wiring layer;
removing the carrier; and
forming a second circuit portion on the second side of the interposer body, wherein the second circuit potion comprises a second insulation layer and a second circuit layer coupled to the second insulation layer and electrically connected to the wiring layer.

7. The method of claim 6, wherein a line width/line spacing of the wiring layer is 0.6/0.6 micron.

8. The method of claim 6, wherein a line width/line spacing of the first circuit layer is greater than the line width/line spacing of the wiring layer.

9. The method of claim 6, wherein a line width/line spacing of the second circuit layer is greater than the line width/line spacing of the wiring layer.

10. The method of claim 6, wherein the interposer body is a back end of line (BEOL) wafer.
